(19) United States
(12) Patent Application Publication
(10) Pub. No.: US 2026/0307114 A1
(43) Pub. Date: Oct. 8, 2026

(54) AIRFLOW-GUIDED CLEANING DEVICE

(71) Applicant: Mu-tech Precision Co., Ltd., Kaohsiung City (TW)

(72) Inventors: Chih-Jen YANG, Taichung City (TW); Kuo-Chang SHIH, Pingtung County (TW); Fan-Ching CHANG, Taichung City (TW)

(73) Assignee: Mu-tech Precision Co., Ltd., Kaohsiung City (TW)

(21) Appl. No.: 19/252,998

(22) Filed: Jun. 27, 2025

(30) Foreign Application Priority Data
Apr. 8, 2025 (TW) 114113229
May 28, 2025 (TW) 114119995

(51) Int. Cl. B08B 3/10; B08B 5/02

(52) U.S. Cl. CPC B08B 3/102; B08B 5/02

(57) ABSTRACT

An airflow-guided cleaning device is adapted for cleaning an object with a cleaning liquid. The airflow-guided cleaning device includes a drive unit, a nozzle seat unit adapted to be disposed above the object, and a nozzle unit. The drive unit includes a carrier member connected to the nozzle seat unit. The nozzle unit is fixedly connected to the nozzle seat unit, and includes a cleaning liquid nozzle member and an airflow nozzle member. The cleaning liquid nozzle member is adapted for ejecting the cleaning liquid downwardly and forwardly. The airflow nozzle member is connected fixedly to a rear end and a lower end of the cleaning liquid nozzle member, and is adapted for emitting a support airflow forwardly and downwardly toward the cleaning liquid such that a position and an impact force of the cleaning liquid ejected from the cleaning liquid nozzle member and applied to the object are adjusted.

### CROSS-REFERENCE TO RELATED APPLICATION

This application claims priority to Taiwanese Invention Patent Application No. 114113229, filed on Apr. 8, 2025, and Taiwanese Invention Patent Application No. 114119995, filed on May 28, 2025, the entire disclosure of which is incorporated by reference herein.

### FIELD

The disclosure relates to a cleaning device, and more particularly to an airflow-guided cleaning device.

### BACKGROUND

A conventional wafer cleaning device for cleaning a wafer surface disclosed in Taiwanese Invention Patent No. I733268 includes a spray container, a nozzle, and a droplet size selection device. The droplet size selection device is connected to the spray container via a first connecting tube, and is connected to an inner core of the nozzle via a second connecting tube. Sizes of droplets and a flow velocity of the droplets may be adjusted and controlled by the droplet size selection device, thereby ensuring cleaning effect of the conventional wafer cleaning device on the wafer surface.

However, the structure of the conventional wafer cleaning apparatus is relatively complex, resulting in a relatively high manufacturing cost.

### SUMMARY

Therefore, an object of the present disclosure is to provide an airflow-guided cleaning device that can alleviate at least one of the drawbacks of the prior art.

According to an aspect of the disclosure, an airflow-guided cleaning device adapted for cleaning an object with a cleaning liquid is provided. The airflow-guided cleaning device includes a base unit, a drive unit, a nozzle seat unit, and at least one nozzle unit. The base unit is adapted for the object to be placed thereon. The drive unit includes a carrier member extending in an up-down direction. The nozzle seat unit is connected to the carrier member, and is adapted to be disposed above the object in the up-down direction. The at least one nozzle unit is fixedly connected to the nozzle seat unit, and includes a cleaning liquid nozzle member and an airflow nozzle member. The cleaning liquid nozzle member is adapted for ejecting the cleaning liquid downwardly in the up-down direction and forwardly in a front-rear direction that is substantially perpendicular to the up-down direction. The airflow nozzle member is connected fixedly to a rear end of the cleaning liquid nozzle member in the front-rear direction and a lower end of the cleaning liquid nozzle member in the up-down direction, and is adapted for emitting a support airflow forwardly and downwardly toward the cleaning liquid ejected from the cleaning liquid nozzle member such that a position and an impact force of the cleaning liquid ejected from the cleaning liquid nozzle member and applied to the object are adjusted.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view of an airflow-guided cleaning device of an embodiment according to the present disclosure and an object to be cleaned.

FIG. 2 is a fragmentary perspective view of the embodiment, illustrating a drive unit, a nozzle seat unit, a plurality of nozzle units, and a second air extraction unit of the embodiment and the object to be cleaned.

FIG. 3 is a fragmentary schematic side view of the embodiment, illustrating a cleaning liquid nozzle member that ejects a cleaning liquid and an airflow nozzle member that emits a support airflow.

FIG. 4 is a fragmentary perspective view illustrating the drive unit, the nozzle seat unit, the nozzle units and the object to be cleaned.

FIG. 5 is a fragmentary schematic front view illustrating the drive unit, the nozzle units, and the object to be cleaned.

FIG. 6 is a partly enlarged view of FIG. 3, illustrating the cleaning liquid nozzle member, the airflow nozzle member, and the object to be cleaned.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

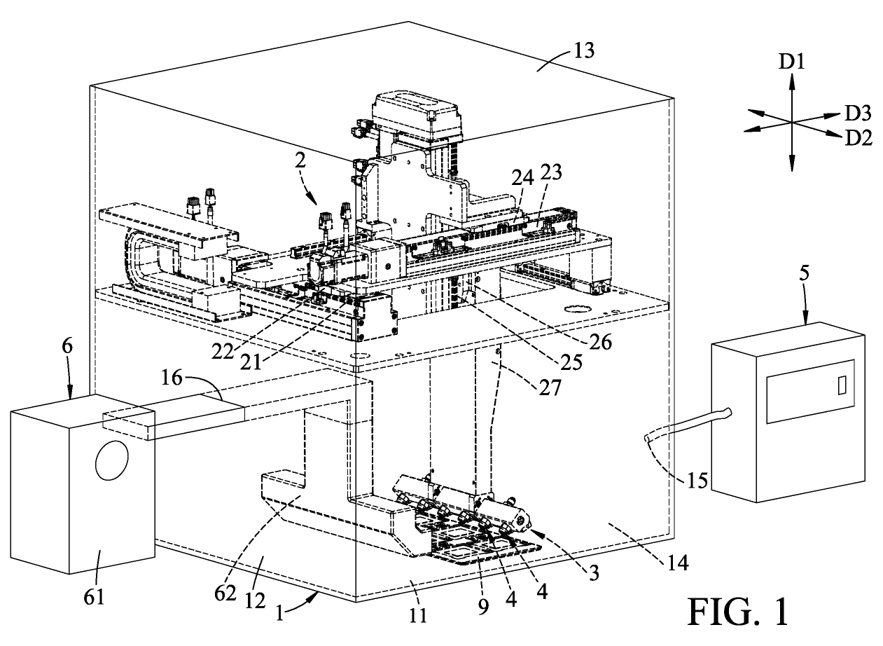

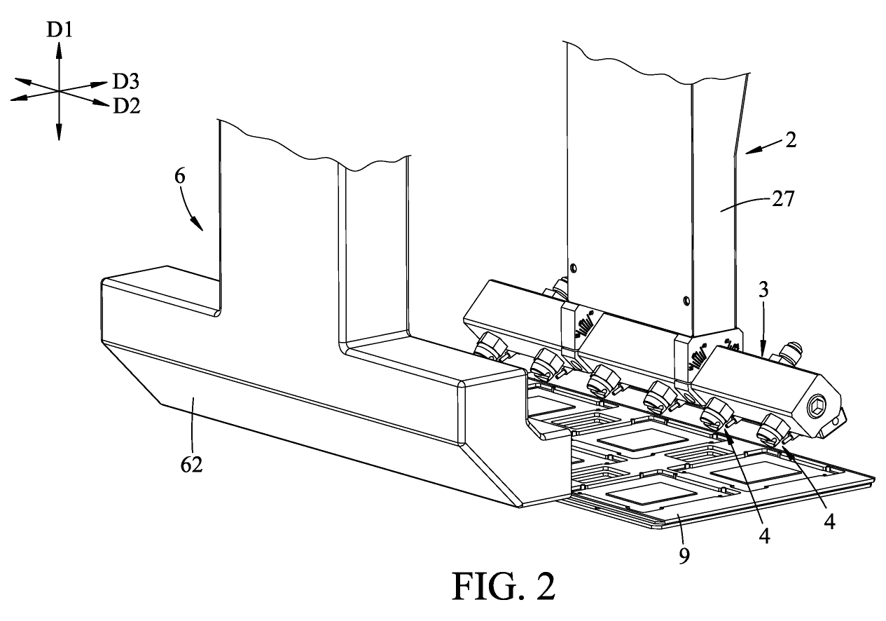

Referring to FIGS. 1 and 2, an airflow-guided cleaning device of an embodiment according to the present disclosure is adapted for cleaning an object 9 by a cleaning liquid. The object 9 may be, but is not limited to, a carrier plate and wafer dies disposed on the carrier plate.

The airflow-guided cleaning device includes a base unit 1, a drive unit 2, a nozzle seat unit 3, a plurality of nozzle units 4, a first air extraction unit 5, and a second air extraction unit 6. In this embodiment, the number of the nozzle units 4 is six. It should be noted that in other embodiments of the present disclosure, the number of the nozzle units 4 may be one to five or more than six.

The base unit 1 is adapted for the object 9 to be placed thereon. The base unit 1 includes a bottom wall 11, a surrounding wall 12 extending upwardly from a top edge of the bottom wall 11 in an up-down direction (D1), and a top wall 13 disposed on a top edge of the surrounding wall 12 in the up-down direction (D1). The bottom wall 11, the surrounding wall 12 and the top wall 13 cooperatively define a cleaning space 14 thereamong.

One of the bottom wall 11, the surrounding wall 12 and the top wall 13 is formed with a first opening 15 in spatial communication with the cleaning space 14. One of the bottom wall 11, the surrounding wall 12 and the top wall 13 is formed with a second opening 16 in spatial communication with the cleaning space 14. In this embodiment, the first opening 15 and the second opening 16 are formed in the surrounding wall 12, and the bottom wall 11 is adapted for the object 9 to be placed thereon.

The drive unit 2 includes a first slide seat 21, a first movable member 22 disposed on the first slide seat 21 and movable in a left-right direction (D2) substantially perpendicular to the up-down direction (D1), a second slide seat 23 mounted to the first movable member 22, a second movable member 24 disposed on the second slide seat 23 and movable in a front-rear direction (D3) that is substantially perpendicular to the up-down direction (D1) and the left-right direction (D2), a third slide seat 25 mounted to the second movable member 24, a third movable member 26 disposed on the third slide seat 25 and movable in the up-down direction (D1), and a carrier member 27 extending in the up-down direction (D1). The carrier member 27 is fixedly connected to the third movable member 26.

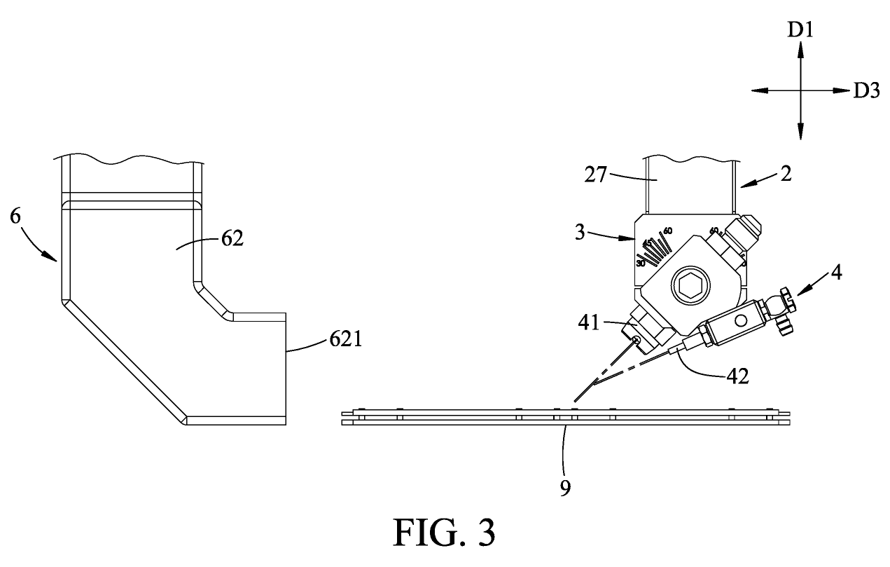

Referring to FIGS. 1 and 3, the nozzle seat unit 3 is connected to the carrier member 27, is disposed in the cleaning space 14, and is in fluid communication with the nozzle units 4 and a storage tank (not shown) that stores the cleaning liquid therein. The nozzle seat unit 3 is adapted to be disposed above the object 9 in the up-down direction (D1). In this embodiment, the nozzle seat unit 3 is rotatably connected to the carrier member 27.

The nozzle units 4 are disposed in the cleaning space 14. In this embodiment, the nozzle units 4 are fixedly connected to the nozzle seat unit 3 and are rotatably mounted to the carrier member 27. In this way, an orientation of each of the nozzle units 4 may be easily adjusted as required.

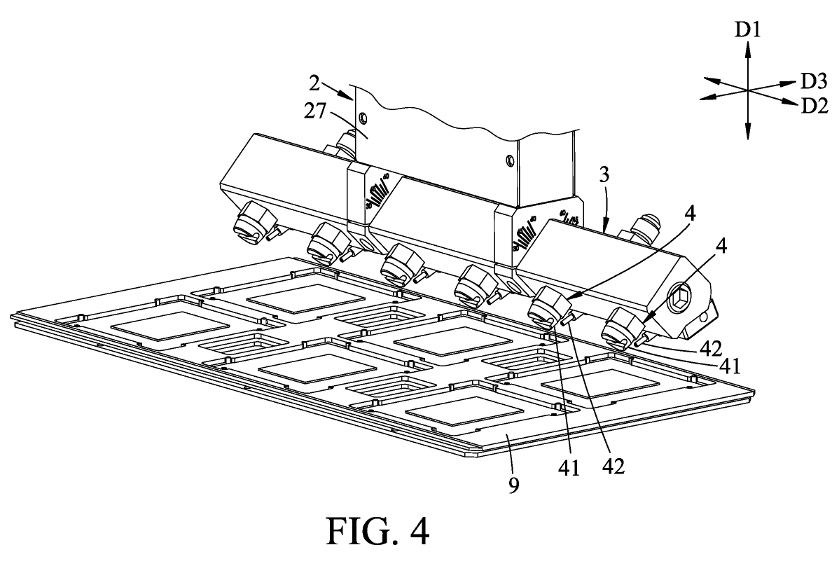

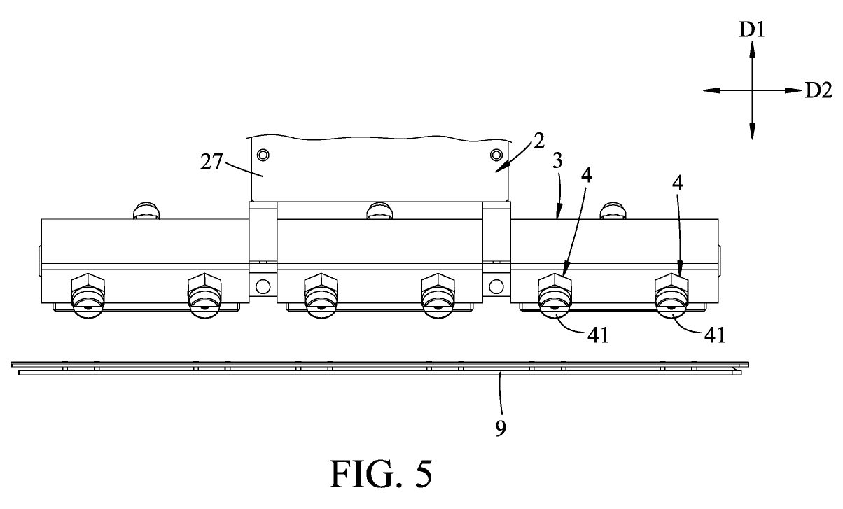

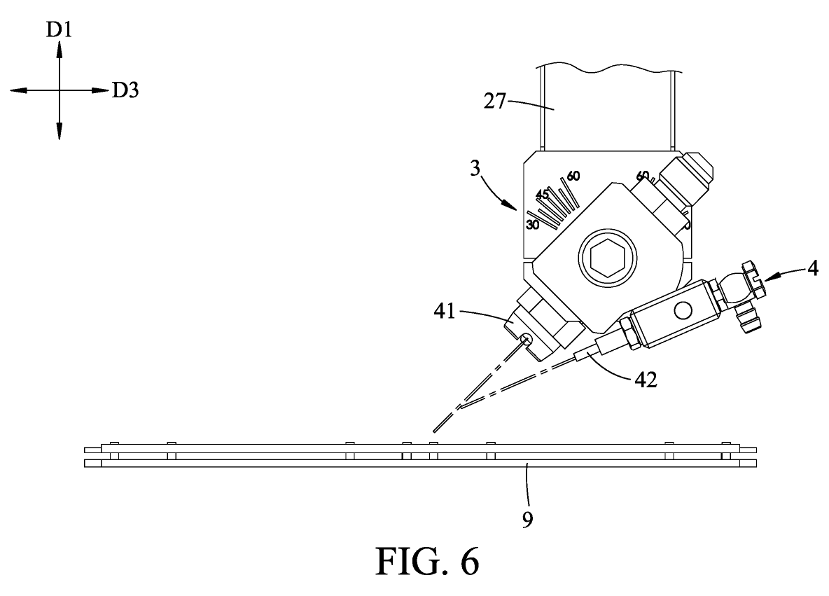

It should be noted that since the structures of the nozzle units 4 are identical, only one of the nozzle units 4 will be described in the following description for the sake of brevity. Referring to FIGS. 4 to 6, the nozzle unit 4 includes a cleaning liquid nozzle member 41 and an airflow nozzle member 42.

The cleaning liquid nozzle member 41 is adapted to be in fluid communication with the storage tank (not shown) via the nozzle seat unit 3, and is adapted for ejecting the cleaning liquid downwardly in the up-down direction (D1) and forwardly in the front-rear direction (D3).

The airflow nozzle member 42 is in spatial communication with an air blower (not shown), is connected fixedly to a rear end of the cleaning liquid nozzle member 41 in the front-rear direction (D3) and a lower end of the cleaning liquid nozzle member 41 in the up-down direction (D1), and is adapted for emitting a support airflow forwardly and downwardly toward the cleaning liquid ejected from the cleaning liquid nozzle member 41, such that a position and an impact force of the cleaning liquid ejected from the cleaning liquid nozzle member 41 and applied to the object 9 are adjusted.

Referring back to FIGS. 1 and 3, the first air extraction unit 5 is in spatial communication with the cleaning space 14 through the first opening 15 to draw air outwardly from the cleaning space 14. In this embodiment, the first air extraction unit 5 is a vacuum pump.

The second air extraction unit 6 includes an exhaust mechanism 61, and an exhaust nozzle member 62 mounted to the exhaust mechanism 61, extending through the second opening 16, and disposed in the cleaning space 14. The exhaust nozzle member 62 has an exhaust opening 621 disposed in the cleaning space 14, and facing the cleaning liquid nozzle member 41 and the airflow nozzle member 42 in the front-rear direction (D3). The exhaust mechanism 61 is adapted for drawing air outwardly from the cleaning space 14 through the exhaust opening 621 of the nozzle member 62. In this embodiment, the exhaust mechanism 61 is an axial fan, a centrifugal fan or a mixed flow fan, but the present disclosure is not limited herein.

It should be noted that in a variation of the present embodiment the surrounding wall 12 and the top wall 13 are omitted from the base unit 1. In this variation, the exhaust mechanism 61 is still capable of drawing air outwardly from the cleaning space 14 through the exhaust nozzle member 62.

An operational flow of cleaning the object 9 performed by the airflow-guided cleaning device of the embodiment is described in the following.

First, the nozzle seat unit 3 and the nozzle units 4 are driven by the drive unit 2 to move toward the object 9.

Then, the cleaning liquid nozzle member 41 ejects the cleaning liquid forwardly in the front-rear direction (D3) and downwardly in the up-down direction (D1).

At the same time, the airflow nozzle member 42 emits the support airflow forwardly and downwardly toward the cleaning liquid such that the position and the impact force of the cleaning liquid ejected from the cleaning liquid nozzle member 41 and applied to the object 9 are adjusted.

At the same time, the exhaust mechanism 61 that faces the cleaning liquid nozzle member 41 and the airflow supporting nozzle member 42 draws air outwardly from the cleaning space 14 through the exhaust nozzle member 62, thereby providing a guided air flow for guiding the cleaning liquid to be ejected forwardly and downwardly.

At the same time, the first air extraction unit 5 draws air outwardly from the cleaning space 14 to reduce air disturbances in the cleaning space 14.

In this way, the airflow-guided cleaning device of the present embodiment may increase the impact force of the cleaning liquid applied to the object 9, such that gaps formed on an upper surface of the object 9 may be cleaned thoroughly.

Thus, the embodiment provides the following effects.

First, by virtue of the arrangements of the cleaning liquid nozzle member 41 and the airflow nozzle member 42, the cleaning liquid is ejected forwardly and downwardly by the cleaning liquid nozzle member 41, and the support air flow emitted by the airflow nozzle member 42 adjusts the position and the impact force of the cleaning liquid applied to the object 9 to ensure that the object 9 is cleaned thoroughly.

Second, by virtue of the first air extraction unit 5 disposed for drawing air outwardly from the cleaning space 14 defined by the bottom wall 11, the surrounding wall 12 and the top wall 13, air disturbances in the cleaning space 14 may be reduced, and the impact force of the cleaning liquid applied to the object 9 downwardly and forwardly may be increased, ensuring that the material 9 is cleaned effectively.

Third, by virtue of the exhaust mechanism 61 being disposed to face the cleaning liquid nozzle member 41 and the airflow supporting nozzle member 42 that draws air from the cleaning space 14 outwardly through the exhaust nozzle member 62, the guided air flow for guiding the cleaning liquid to be ejected forwardly and downwardly in a smooth manner may be provided, so the impact force of the cleaning liquid applied to the object 9 is also increased, which ensures that the object 9 may be cleaned effectively.

To sum up, the airflow-guided cleaning device of the embodiment may effectively clean the object 9 to achieve the purpose of the present disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An airflow-guided cleaning device adapted for cleaning an object with a cleaning liquid, said airflow-guided cleaning device comprising:
a base unit that is adapted for the object to be placed thereon;
a drive unit that includes a carrier member extending in an up-down direction;
a nozzle seat unit connected to said carrier member and adapted to be disposed above the object in the up-down direction; and
at least one nozzle unit that is fixedly connected to said nozzle seat unit and that includes a cleaning liquid nozzle member and an airflow nozzle member, said cleaning liquid nozzle member adapted for ejecting the cleaning liquid downwardly in the up-down direction and forwardly in a front-rear direction that is substantially perpendicular to the up-down direction, said airflow nozzle member connected fixedly to a rear end of said cleaning liquid nozzle member in the front-rear direction and a lower end of said cleaning liquid nozzle member in the up-down direction, and adapted for emitting a support airflow forwardly and downwardly toward the cleaning liquid ejected from said cleaning liquid nozzle member such that a position and an impact force of the cleaning liquid ejected from said cleaning liquid nozzle member and applied to the object are adjusted.

2. The airflow-guided cleaning device as claimed in claim 1, wherein:
said base unit includes a bottom wall, a surrounding wall extending upwardly from a top edge of said bottom wall in the up-down direction, and a top wall disposed on a top edge of said surrounding wall in the up-down direction;
said bottom wall, said surrounding wall and said top wall cooperatively define a cleaning space thereamong; and
said nozzle seat unit and said at least one nozzle unit are disposed in said cleaning space, and said bottom wall is adapted for the object to be placed thereon.

3. The airflow-guided cleaning device as claimed in claim 2, wherein:
said airflow-guided cleaning device further comprises a first air extraction unit;
one of said bottom wall, said surrounding wall and said top wall is formed with a first opening in spatial communication with said cleaning space; and
said first air extraction unit is in spatial communication with said cleaning space through said first opening to draw air outwardly from said cleaning space.

4. The airflow-guided cleaning device as claimed in claim 3, wherein:
said airflow-guided cleaning device further comprises a second air extraction unit;
one of said bottom wall, said surrounding wall and said top wall is formed with a second opening in spatial communication with said cleaning space;
said second air extraction unit includes an exhaust mechanism, and an exhaust nozzle member mounted to said exhaust mechanism, extending through said second opening, and disposed in said cleaning space;
said exhaust nozzle member has an exhaust opening disposed in said cleaning space, and facing said cleaning liquid nozzle member and said airflow nozzle member in the front-rear direction; and
said exhaust mechanism is adapted for drawing air outwardly from said cleaning space through said exhaust opening of said exhaust nozzle member.

5. The airflow-guided cleaning device as claimed in claim 1, wherein:
said airflow-guided cleaning device further comprises a second air extraction unit;
said second air extraction unit includes an exhaust mechanism, and an exhaust nozzle member mounted to said exhaust mechanism and disposed in said cleaning space;
said exhaust nozzle member has an exhaust opening disposed in said cleaning space, and facing said cleaning liquid nozzle member and said airflow nozzle member in the front-rear direction; and
said exhaust mechanism is adapted for drawing air outwardly from said cleaning space through said exhaust opening of said exhaust nozzle member.

6. The airflow-guided cleaning device as claimed in claim 1, wherein said nozzle seat unit and said at least one nozzle unit are rotatably mounted to said carrier member.

7. The airflow-guided cleaning device as claimed in claim 1, wherein:
said drive unit further includes
a first slide seat,
a first movable member disposed on said first slide seat and movable in a left-right direction that is substantially perpendicular to the up-down direction and the front-rear direction,
a second slide seat mounted to said first movable member,
a second movable member disposed on said second slide seat and movable in the front-rear direction,
a third slide seat mounted to said second movable member, and
a third movable member disposed on said third slide seat and movable in the up-down direction; and
said carrier member is connected fixedly to said third movable member.
